(19) United States
(12) Patent Application Publication
(10) Pub. No.: US 2006/0130966 A1
(43) Pub. Date: Jun. 22, 2006

(54) Method and system for flowing a supercritical fluid in a high pressure processing system

(76) Inventors: Darko Babic, Chandler, AZ (US); Eric J. Strang, Chandler, AZ (US)

Correspondence Address: WOOD, HERRON & EVANS, LLP (TOKYO ELECTRON), 2700 CAREW TOWER, 441 VINE STREET, CINCINNATI, OH, 45202, US

(21) Appl. No.: 11/018,922

(22) Filed: Dec. 20, 2004

(51) Int. Cl. H01L 21/306

(52) U.S. Cl. 156/345.1

(57) ABSTRACT

A method and system is described for treating a substrate with a supercritical fluid using a high temperature process. For example, when the supercritical fluid includes carbon dioxide in a supercritical state, the high temperature process is performed at a temperature approximately equal to and exceeding 80 degrees C., which is greater than the critical temperature of approximately 31 degrees C.

### BACKGROUND OF THE INVENTION

1. Field of the Invention

The present invention relates to a method and system for flowing a supercritical fluid in a high pressure processing system and, more particularly, to a method and system for providing a substantially uniform flow of supercritical fluid across a substrate in a supercritical processing system.

2. Description of Related Art

During the fabrication of semiconductor devices for integrated circuits (ICs), a sequence of material processing steps, including both pattern etching and deposition processes, are performed, whereby material is removed from or added to a substrate surface, respectively. During, for instance, pattern etching, a pattern formed in a mask layer of radiation-sensitive material, such as photoresist, using for example photolithography, is transferred to an underlying thin material film using a combination of physical and chemical processes to facilitate the selective removal of the underlying material film relative to the mask layer.

Thereafter, the remaining radiation-sensitive material, or photoresist, and post-etch residue, such as hardened photoresist and other etch residues, are removed using one or more cleaning processes. Conventionally, these residues are removed by performing plasma ashing in an oxygen plasma, followed by wet cleaning through immersion of the substrate in a liquid bath of stripper chemicals.

Until recently, dry plasma ashing and wet cleaning were found to be sufficient for removing residue and contaminants accumulated during semiconductor processing. However, recent advancements for ICs include a reduction in the critical dimension for etched features below a feature dimension acceptable for wet cleaning, such as a feature dimension below approximately 45 to 65 nanometers (nm). Moreover, the advent of new materials, such as low dielectric constant (low-k) materials, limits the use of plasma ashing due to their susceptibility to damage during plasma exposure.

Therefore, at present, interest has developed for the replacement of dry plasma ashing and wet cleaning. One interest includes the development of dry cleaning systems utilizing a supercritical fluid as a carrier for a solvent, or other residue removing composition. At present, the inventors have recognized that conventional processes are deficient in, for example, uniformly cleaning residue from a substrate, particularly those substrates following complex etching processes, or having high aspect ratio features.

At present, the inventors have further recognized that conventional processing systems offer insufficient control of the flow, or velocity field, of the supercritical fluid over the substrate to be treated and, furthermore, such systems suffer from particulate contamination.

### SUMMARY OF THE INVENTION

One object of the invention is to provide a method and system for flowing a high pressure fluid in a high pressure processing system.

Another object of the invention is to provide a method and system of providing a substantially uniform flow of a high pressure fluid in a high pressure processing system.

According to one embodiment, a processing system for treating a substrate is provided comprising: a processing chamber configured to treat the substrate; a platen coupled to the processing chamber, and configured to support the substrate beneath a ceiling of the processing chamber; a fluid supply system coupled to the processing chamber, and configured to introduce a high pressure fluid to the processing chamber; a fluid flow system coupled to the fluid supply system, and configured to flow the high pressure fluid through the processing chamber over the substrate; one or more inlets coupled to the fluid flow system, and configured to introduce the high pressure fluid to the processing chamber through the ceiling at a substantially center portion of the substrate; and one or more outlets positioned beyond a peripheral edge of the substrate, and configured to discharge the high pressure fluid from the processing chamber, wherein a height between the ceiling and an upper surface of the substrate monotonically decreases with radial position across the substrate from the substantially center portion of the substrate to the peripheral edge of the substrate. The ceiling, as used herein, can be the top of the processing chamber, a dome or a plate, or any other structure configured to confine fluid flow between it and a substrate supported on the platen.

### BRIEF DESCRIPTION OF THE DRAWINGS

In the accompanying drawings:

FIG. 1 presents a simplified schematic representation of a processing system;

FIG. 2A depicts a system configured to cool a pump;

FIG. 2B depicts another system configured to cool a pump;

FIG. 3 presents another simplified schematic representation of a processing system;

FIG. 4 presents another simplified schematic representation of a processing system;

FIGS. 5A and 5B depict a fluid injection manifold for introducing fluid to a processing system;

FIG. 6 presents a processing system according to an embodiment;

FIG. 7 illustrates an exemplary profile of the total velocity across a substrate in a processing system according to another embodiment; and

FIG. 8 illustrates a method of treating a substrate in a processing system according to an embodiment of the invention.

### DETAILED DESCRIPTION OF EXEMPLARY EMBODIMENTS

In the following description, to facilitate a thorough understanding of the invention and for purposes of explanation and not limitation, specific details are set forth, such as a particular geometry of the processing system and various descriptions of the system components. However, it should be understood that the invention may be practiced with other embodiments that depart from these specific details.

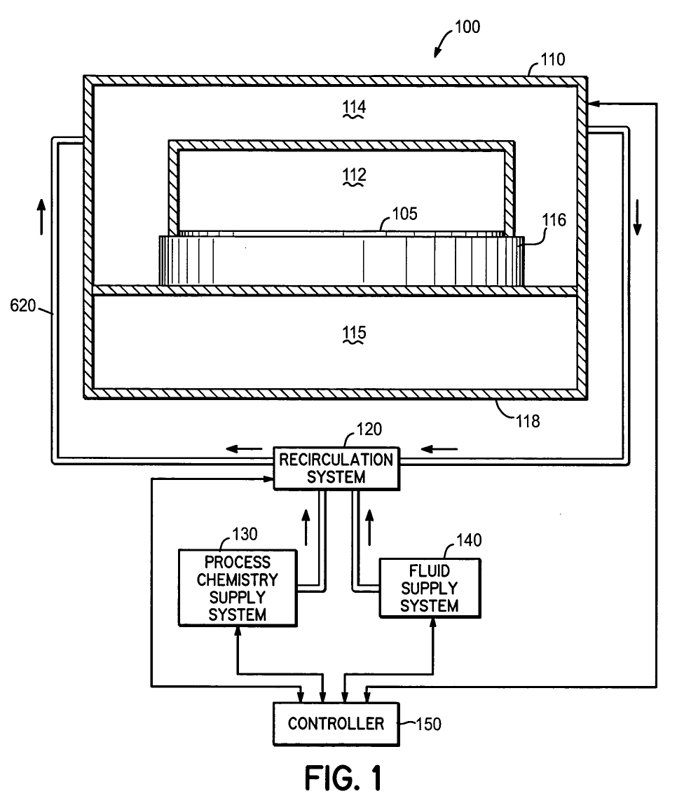

Referring now to the drawings, wherein like reference numerals designate identical or corresponding parts throughout the several views, FIG. 1 illustrates a processing system 100 according to an embodiment of the invention. In the illustrated embodiment, processing system 100 is configured to treat a substrate 105 with a high pressure fluid, such as a fluid in a supercritical state, with or without other additives, such as process chemistry. The processing system 100 comprises processing elements that include a processing chamber 110, a fluid flow system 120, a process chemistry supply system 130, a high pressure fluid supply system 140, and a controller 150, all of which are configured to process substrate 105. The controller 150 can be coupled to the processing chamber 110, the fluid flow system 120, the process chemistry supply system 130, and the high pressure fluid supply system 140.

Alternately, or in addition, controller 150 can be coupled to a one or more additional controllers/computers (not shown), and controller 150 can obtain setup and/or configuration information from an additional controller/computer.

In FIG. 1, singular processing elements (110, 120, 130, 140, and 150) are shown, but this is not required for the invention. The processing system 100 can comprise any number of processing elements having any number of controllers associated with them in addition to independent processing elements.

The controller 150 can be used to configure any number of processing elements (110, 120, 130, and 140), and the controller 150 can collect, provide, process, store, and display data from processing elements. The controller 150 can comprise a number of applications for controlling one or more of the processing elements. For example, controller 150 can include a graphic user interface (GUI) component (not shown) that can provide easy to use interfaces that enable a user to monitor and/or control one or more processing elements.

Referring still to FIG. 1, the fluid flow system 120 is configured to flow fluid and chemistry from the supplies 130 and 140 through the processing chamber 110. The fluid flow system 120 is illustrated as a recirculation system through which the fluid and chemistry recirculate from and back to the processing chamber 110 via primary flow line 620. This recirculation is most likely to be the preferred configuration for many applications, but this is not necessary to the invention. Fluids, particularly inexpensive fluids, can be passed through the processing chamber 110 once and then discarded, which might be more efficient than reconditioning them for re-entry into the processing chamber. Accordingly, while the fluid flow system or recirculation system 120 is described as a recirculating system in the exemplary embodiments, a non-recirculating system may, in some cases, be substituted. This fluid flow system 120 can include one or more valves (not shown) for regulating the flow of a processing solution through the fluid flow system 120 and through the processing chamber 110. The fluid flow system 120 can comprise any number of back-flow valves, filters, pumps, and/or heaters (not shown) for maintaining a specified temperature, pressure or both for the processing solution and for flowing the process solution through the fluid flow system 120 and through the processing chamber 110. Furthermore, any one of the many components provided within the fluid flow system 120 may be heated to a temperature consistent with the specified process temperature.

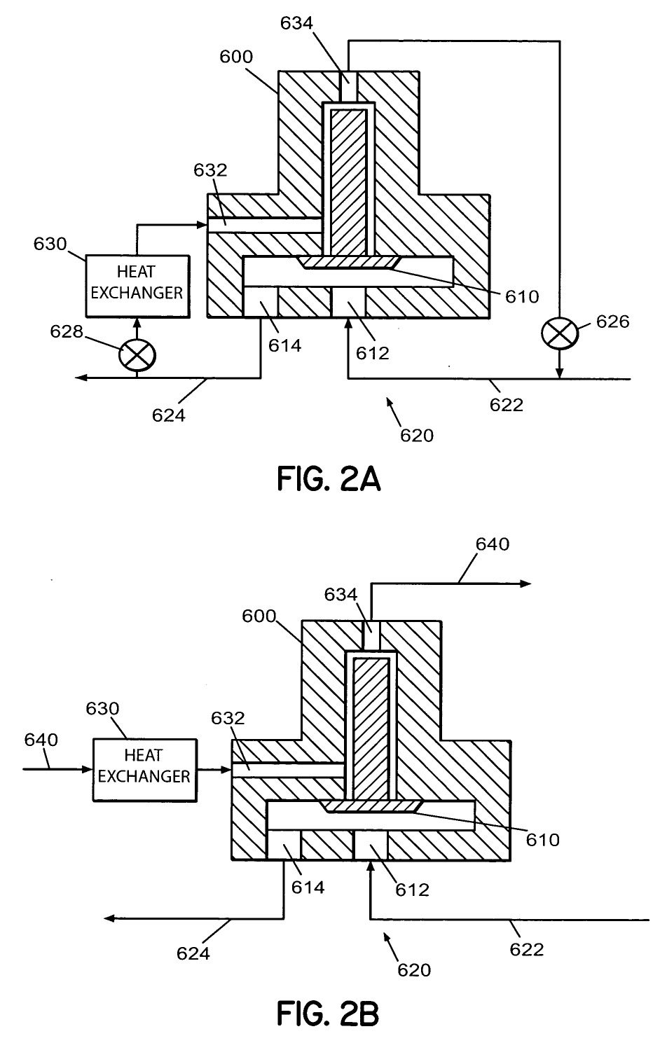

Some components, such as a fluid flow or recirculation pump, may require cooling in order to permit proper functioning. For example, some commercially available pumps, having specifications required for processing performance at high pressure and cleanliness during supercritical processing, comprise components that are limited in temperature. Therefore, as the temperature of the fluid and structure are elevated, cooling of the pump is required to maintain its functionality. Fluid flow system 120 for circulating the supercritical fluid through processing chamber 110 can comprise the primary flow line 620 coupled to high pressure processing system 100, and configured to supply the supercritical fluid at a fluid temperature equal to or greater than 40 degrees C. to the high pressure processing system 100, and a high temperature pump 600, shown and described below with reference to FIGS. 2A and 2B, coupled to the primary flow line 620. The high temperature pump 600 can be configured to move the supercritical fluid through the primary flow line 620 to the processing chamber 110, wherein the high temperature pump comprises a coolant inlet configured to receive a coolant and a coolant outlet configured to discharge the coolant. A heat exchanger coupled to the coolant inlet can be configured to lower a coolant temperature of the coolant to a temperature less than or equal to the fluid temperature of the supercritical fluid.

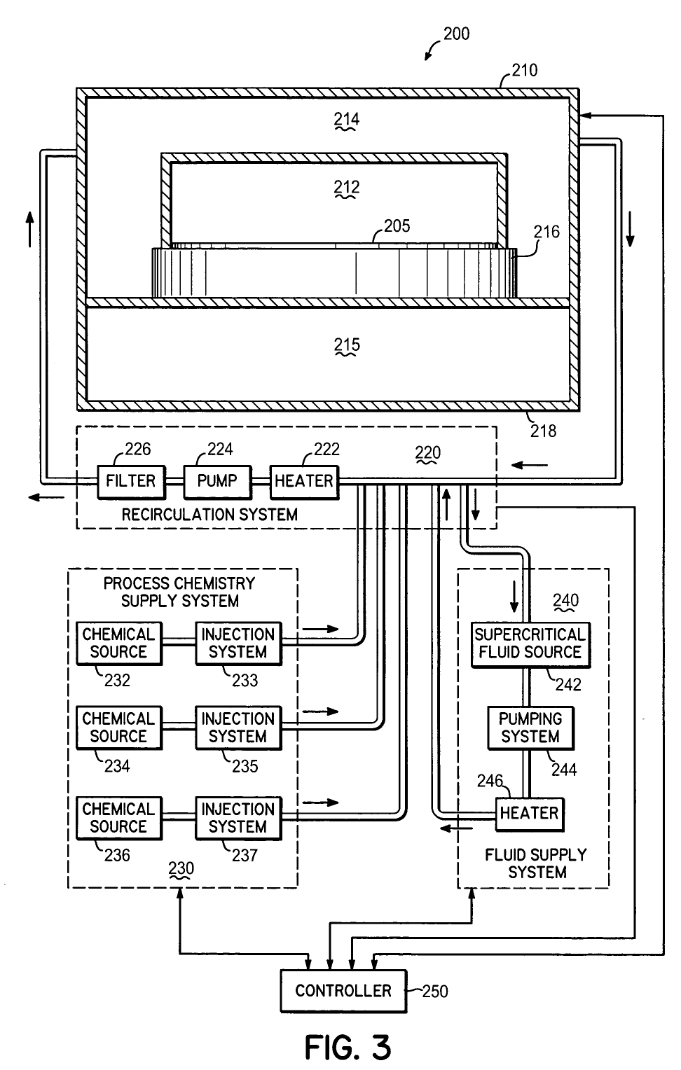

As illustrated in FIG. 2A, one embodiment is provided for cooling a high temperature pump 600 associated with fluid flow system 120 (or 220 described below with reference to FIG. 3) by diverting high pressure fluid from a primary flow line 620 to the high pressure processing chamber 110 (or 210) through a heat exchanger 630, through the pump 600, and back to the primary flow line 620. For example, a pump impeller 610 housed within pump 600 can move high pressure fluid from a suction side 622 of primary flow line 620 through an inlet 612 and through an outlet 614 to a pressure side 624 of the primary flow line 620. A fraction of high pressure fluid can be diverted through an inlet valve 628, through heat exchanger 630, and enter pump 600 through coolant inlet 632. Thereafter, the fraction of high pressure fluid utilized for cooling can exit from pump 600 at coolant outlet 634 and return to the primary flow line 620 through outlet valve 626.

Alternatively, as illustrated in FIG. 2B, another embodiment is provided for cooling pump 600 using a secondary flow line 640. A high pressure fluid, such as a supercritical fluid, from a fluid source (not shown) is directed through heat exchanger 630 (to lower the temperature of the fluid), and then enters pump 600 through coolant inlet 632, passes through pump 600, exits through coolant outlet 634, and continues to a discharge system (not shown). The fluid source can include a supercritical fluid source, such as a supercritical carbon dioxide source. The fluid source may or may not be a member of the high pressure fluid supply system 140 (or 240) described in FIG. 1 (or FIG. 3). The discharge system can include a vent, or the discharge system can include a recirculation system having a pump configured to recirculate the high pressure fluid through the heat exchanger 630 and pump 600.

Additional details regarding pump design are provided in co-pending U.S. patent application Ser. No. 10/987,066, entitled “Method and System for Cooling a Pump”; the entire content of which is herein incorporated by reference in its entirety.

Referring again to FIG. 1, the processing system 100 can comprise high pressure fluid supply system 140. The high pressure fluid supply system 140 can be coupled to the fluid flow system 120, but this is not required. In alternate embodiments, high pressure fluid supply system 140 can be configured differently and coupled differently. For example, the fluid supply system 140 can be coupled directly to the processing chamber 110. The high pressure fluid supply system 140 can include a supercritical fluid supply system. A supercritical fluid as referred to herein is a fluid that is in a supercritical state, which is that state that exists when the fluid is maintained at or above the critical pressure and at or above the critical temperature on its phase diagram. In such a supercritical state, the fluid possesses certain properties, one of which is the substantial absence of surface tension. Accordingly, a supercritical fluid supply system, as referred to herein, is one that delivers to a processing chamber a fluid that assumes a supercritical state at the pressure and temperature at which the processing chamber is being controlled. Furthermore, it is only necessary that at least at or near the critical point the fluid is in substantially a supercritical state at which its properties are sufficient, and exist long enough, to realize their advantages in the process being performed. Carbon dioxide, for example, is a supercritical fluid when maintained at or above a pressure of about 1,070 psi at a temperature of 31 degrees C. This state of the fluid in the processing chamber may be maintained by operating the processing chamber at 2,000 to 10,000 psi at a temperature of approximately 40 degrees C. or greater.

As described above, the fluid supply system 140 can include a supercritical fluid supply system, which can be a carbon dioxide supply system. For example, the fluid supply system 140 can be configured to introduce a high pressure fluid having a pressure substantially near the critical pressure for the fluid. Additionally, the fluid supply system 140 can be configured to introduce a supercritical fluid, such as carbon dioxide in a supercritical state. Additionally, for example, the fluid supply system 140 can be configured to introduce a supercritical fluid, such as supercritical carbon dioxide, at a pressure ranging from approximately the critical pressure of carbon dioxide to 10,000 psi. Examples of other supercritical fluid species useful in the broad practice of the invention include, but are not limited to, carbon dioxide (as described above), oxygen, argon, krypton, xenon, ammonia, methane, methanol, dimethyl ketone, hydrogen, water, and sulfur hexafluoride. The fluid supply system can, for example, comprise a carbon dioxide source (not shown) and a plurality of flow control elements (not shown) for generating a supercritical fluid. For example, the carbon dioxide source can include a CO₂ feed system, and the flow control elements can include supply lines, valves, filters, pumps, and heaters. The fluid supply system 140 can comprise an inlet valve (not shown) that is configured to open and close to allow or prevent the stream of supercritical carbon dioxide from flowing into the processing chamber 110. For example, controller 150 can be used to determine fluid parameters such as pressure, temperature, process time, and flow rate.

Referring still to FIG. 1, the process chemistry supply system 130 is coupled to the recirculation system 120, but this is not required for the invention. In alternate embodiments, the process chemistry supply system 130 can be configured differently, and can be coupled to different elements in the processing system 100. The process chemistry is introduced by the process chemistry supply system 130 into the fluid introduced by the fluid supply system 140 at ratios that vary with the substrate properties, the chemistry being used and the process being performed in the processing chamber 110. Usually the ratio is roughly 1 to 15 percent by volume in systems where the chamber, recirculation system and associated plumbing have a volume of about one liter. This amounts to about 10 to 150 milliliters of additive in most cases. The ratio may be higher or lower.

The process chemistry supply system 130 can be configured to introduce one or more of the following process compositions, but not limited to: cleaning compositions for removing contaminants, residues, hardened residues, photoresist, hardened photoresist, post-etch residue, post-ash residue, post chemical-mechanical polishing (CMP) residue, post-polishing residue, or post-implant residue, or any combination thereof; cleaning compositions for removing particulate; drying compositions for drying thin films, porous thin films, porous low dielectric constant materials, or air-gap dielectrics, or any combination thereof; film-forming compositions for preparing dielectric thin films, metal thin films, or any combination thereof; healing compositions for restoring the dielectric constant of low dielectric constant (low-k) films; sealing compositions for sealing porous films; or any combination thereof. Additionally, the process chemistry supply system 130 can be configured to introduce solvents, co-solvents, surfactants, etchants, acids, bases, chelators, oxidizers, film-forming precursors, or reducing agents, or any combination thereof.

The process chemistry supply system 130 can be configured to introduce N-methylpyrrolidone (NMP), diglycol amine, hydroxylamine, di-isopropyl amine, tri-isoprpyl amine, tertiary amines, catechol, ammonium fluoride, ammonium bifluoride, methylacetoacetamide, ozone, propylene glycol monoethyl ether acetate, acetylacetone, dibasic esters, ethyl lactate, CHF₃, BF₃, HF, other fluorine containing chemicals, or any mixture thereof. Other chemicals such as organic solvents may be utilized independently or in conjunction with the above chemicals to remove organic materials. The organic solvents may include, for example, an alcohol, ether, and/or glycol, such as acetone, diacetone alcohol, dimethyl sulfoxide (DMSO), ethylene glycol, methanol, ethanol, propanol, or isopropanol (IPA). For further details, see U.S. Pat. No. 6,306,564B1, filed May 27, 1998, and titled “Removal of Resist or Residue from Semiconductors Using Supercritical Carbon Dioxide”, and U.S. Pat. No. 6,509,141B2, filed Sep. 3, 1999, and titled “Removal of Photoresist and Photoresist Residue from Semiconductors Using Supercritical Carbon dioxide Process,” both incorporated by reference herein.

Additionally, the process chemistry supply system 130 can comprise a cleaning chemistry assembly (not shown) for providing cleaning chemistry for generating supercritical cleaning solutions within the processing chamber. The cleaning chemistry can include peroxides and a fluoride source. For example, the peroxides can include hydrogen peroxide, benzoyl peroxide, or any other suitable peroxide, and the fluoride sources can include fluoride salts (such as ammonium fluoride salts), hydrogen fluoride, fluoride adducts (such as organo-ammonium fluoride adducts), and combinations thereof. Further details of fluoride sources and methods of generating supercritical processing solutions with fluoride sources are described in U.S. patent application Ser. No. 10/442,557, filed May 20, 2003, and titled “Tetra-Organic Ammonium Fluoride and HF in Supercritical Fluid for Photoresist and Residue Removal”, and U.S. patent application Ser. No. 10/321,341, filed Dec. 16, 2002, and titled “Fluoride in Supercritical Fluid for Photoresist Polymer and Residue Removal,” both incorporated by reference herein.

Furthermore, the process chemistry supply system 130 can be configured to introduce chelating agents, complexing agents and other oxidants, organic and inorganic acids that can be introduced into the supercritical fluid solution with one or more carrier solvents, such as N,N-dimethylacetamide (DMAc), gamma-butyrolactone (BLO), dimethyl sulfoxide (DMSO), ethylene carbonate (EC), N-methylpyrrolidone (NMP), dimethylpiperidone, propylene carbonate, and alcohols (such a methanol, ethanol and 2-propanol).

Moreover, the process chemistry supply system 130 can comprise a rinsing chemistry assembly (not shown) for providing rinsing chemistry for generating supercritical rinsing solutions within the processing chamber. The rinsing chemistry can include one or more organic solvents including, but not limited to, alcohols and ketone. In one embodiment, the rinsing chemistry can comprise sulfolane, also known as thiocyclopentane-1,1-dioxide, (cyclo)tetramethylene sulphone and 2,3,4,5-tetrahydrothiophene-1,1-dioxide, which can be purchased from a number of venders, such as Degussa Stanlow Limited, Lake Court, Hursley Winchester SO21 2LD UK.

Moreover, the process chemistry supply system 130 can be configured to introduce treating chemistry for curing, cleaning, healing (or restoring the dielectric constant of low-k materials), or sealing, or any combination, low dielectric constant films (porous or non-porous). The chemistry can include hexamethyldisilazane (HMDS), chlorotrimethylsilane (TMCS), trichloromethylsilane (TCMS), dimethylsilyldiethylamine (DMSDEA), tetramethyldisilazane (TMDS), trimethylsilyldimethylamine (TMSDMA), dimethylsilyldimethylamine (DMSDMA), trimethylsilyldiethylamine (TMSDEA), bistrimethylsilyl urea (BTSU), bis(dimethylamino)methyl silane (B[DMA]MS), bis (dimethylamino)dimethyl silane (B[DMA]DS), HMCTS, dimethylaminopentamethyldisilane (DMAPMDS), dimethylaminodimethyldisilane (DMADMDS), disila-aza-cyclopentane (TDACP), disila-oza-cyclopentane (TDOCP), methyltrimethoxysilane (MTMOS), vinyltrimethoxysilane (VTMOS), or trimethylsilylimidazole (TMSI). Additionally, the chemistry may include N-tert-butyl-1,1-dimethyl-1-(2,3,4,5-tetramethyl-2,4-cyclopentadiene-1-yl)silanamine, 1,3-diphenyl-1,1,3,3-tetramethyldisilazane, or tert-butylchlorodiphenylsilane. For further details, see U.S. patent application Ser. No. 10/682,196, filed Oct. 10, 2003, and titled “Method and System for Treating a Dielectric Film,” and U.S. patent application Ser. No. 10/379,984, filed Mar. 4, 2003, and titled “Method of Passivating Low Dielectric Materials in Wafer Processing,” both incorporated by reference herein.

Additionally, the process chemistry supply system 130 can be configured to introduce peroxides during, for instance, cleaning processes. The peroxides can include organic peroxides, or inorganic peroxides, or a combination thereof. For example, organic peroxides can include 2-butanone peroxide; 2,4-pentanedione peroxide; peracetic acid; t-butyl hydroperoxide; benzoyl peroxide; or m-chloroperbenzoic acid (mCPBA). Other peroxides can include hydrogen peroxide.

The processing chamber 110 can be configured to process substrate 105 by exposing the substrate 105 to fluid from the fluid supply system 140, or process chemistry from the process chemistry supply system 130, or a combination thereof in a processing space 112. Additionally, processing chamber 110 can include an upper chamber assembly 114, and a lower chamber assembly 115.

The upper chamber assembly 114 can comprise a heater (not shown) for heating the processing chamber 110, the substrate 105, or the processing fluid, or a combination of two or more thereof. Alternately, a heater is not required. Additionally, the upper chamber assembly 114 can include flow components for flowing a processing fluid through the processing chamber 110. In one embodiment, the high pressure fluid is introduced to the processing chamber 110 through a ceiling formed in the upper chamber assembly 114 and located above substrate 105 through one or more inlets located above a substantially center portion of substrate 105. The high pressure fluid flows radially outward across an upper surface of substrate 105 beyond a peripheral edge of substrate 105, and discharges through one or more outlets, wherein the spacing between the upper surface of substrate 105 and the ceiling decreases with radial position from proximate the substantially center portion of substrate 105 to the peripheral edge of substrate 105.

The lower chamber assembly 115 can include a platen 116 configured to support substrate 105 and a drive mechanism 118 for translating the platen 116 in order to load and unload substrate 105, and seal lower chamber assembly 115 with upper chamber assembly 114. The platen 116 can also be configured to heat or cool the substrate 105 before, during, and/or after processing the substrate 105. For example, the platen 116 can include one or more heater rods configured to elevate the temperature of the platen to approximately 31 degrees C. or greater. Additionally, the lower assembly 115 can include a lift pin assembly for displacing the substrate 105 from the upper surface of the platen 116 during substrate loading and unloading.

Additionally, controller 150 includes a temperature control system coupled to one or more of the processing chamber 110, the fluid flow system 120 (or recirculation system), the platen 116, the high pressure fluid supply system 140, or the process chemistry supply system 130. The temperature control system is coupled to heating elements embedded in one or more of these systems, and configured to elevate the temperature of the supercritical fluid to approximately 31 degrees C. or greater. The heating elements can, for example, include resistive heating elements.

A transfer system (not shown) can be used to move a substrate into and out of the processing chamber 110 through a slot (not shown). In one example, the slot can be opened and closed by moving the platen 116, and in another example, the slot can be controlled using a gate valve (not shown).

The substrate can include semiconductor material, metallic material, dielectric material, ceramic material, or polymer material, or a combination of two or more thereof. The semiconductor material can include Si, Ge, Si/Ge, or GaAs. The metallic material can include Cu, Al, Ni, Pb, Ti, and/or Ta. The dielectric material can include silica, silicon dioxide, quartz, aluminum oxide, sapphire, low dielectric constant materials, TEFLON®, and/or polyimide. The ceramic material can include aluminum oxide, silicon carbide, etc.

The processing system 100 can also comprise a pressure control system (not shown). The pressure control system can be coupled to the processing chamber 110, but this is not required. In alternate embodiments, the pressure control system can be configured differently and coupled differently. The pressure control system can include one or more pressure valves (not shown) for exhausting the processing chamber 110 and/or for regulating the pressure within the processing chamber 110. Alternately, the pressure control system can also include one or more pumps (not shown). For example, one pump may be used to increase the pressure within the processing chamber, and another pump may be used to evacuate the processing chamber 110. In another embodiment, the pressure control system can comprise seals for sealing the processing chamber. In addition, the pressure control system can comprise an elevator for raising and lowering the substrate 105 and/or the platen 116.

Furthermore, the processing system 100 can comprise an exhaust control system. The exhaust control system can be coupled to the processing chamber 110, but this is not required. In alternate embodiments, the exhaust control system can be configured differently and coupled differently. The exhaust control system can include an exhaust gas collection vessel (not shown) and can be used to remove contaminants from the processing fluid. Alternately, the exhaust control system can be used to recycle the processing fluid.

Referring now to FIG. 3, a processing system 200 is presented according to another embodiment. In the illustrated embodiment, processing system 200 comprises a processing chamber 210, a recirculation system 220, a process chemistry supply system 230, a fluid supply system 240, and a controller 250, all of which are configured to process substrate 205. The controller 250 can be coupled to the processing chamber 210, the recirculation system 220, the process chemistry supply system 230, and the fluid supply system 240. Alternately, controller 250 can be coupled to a one or more additional controllers/computers (not shown), and controller 250 can obtain setup and/or configuration information from an additional controller/computer.

As shown in FIG. 3, the recirculation system 220 can include a recirculation fluid heater 222, a pump 224, and a filter 226. The process chemistry supply system 230 can include one or more chemistry introduction systems, each introduction system having a chemical source 232, 234, 236 and an injection system 233, 235, 237. The injection systems 233, 235, 237 can include a pump (not shown) and an injection valve (not shown).

Additional details regarding injection of process chemistry are provided in co-pending U.S. patent application Ser. No. 10/957,417, entitled “Method and System for Injecting Chemistry into a Supercritical Fluid”; the entire content of which is herein incorporated by reference in its entirety.

Furthermore, the fluid supply system 240 can include a supercritical fluid source 242, a pumping system 244, and a supercritical fluid heater 246. In addition, one or more injection valves, and/or exhaust valves may be utilized with the fluid supply system 240.

The processing chamber 210 can be configured to process substrate 205 by exposing the substrate 205 to fluid from the fluid supply system 240, or process chemistry from the process chemistry supply system 230, or a combination thereof in a processing space 212. Additionally, processing chamber 210 can include an upper chamber assembly 214, and a lower chamber assembly 215 having a platen 216 and drive mechanism 218, as described above with reference to FIG. 1.

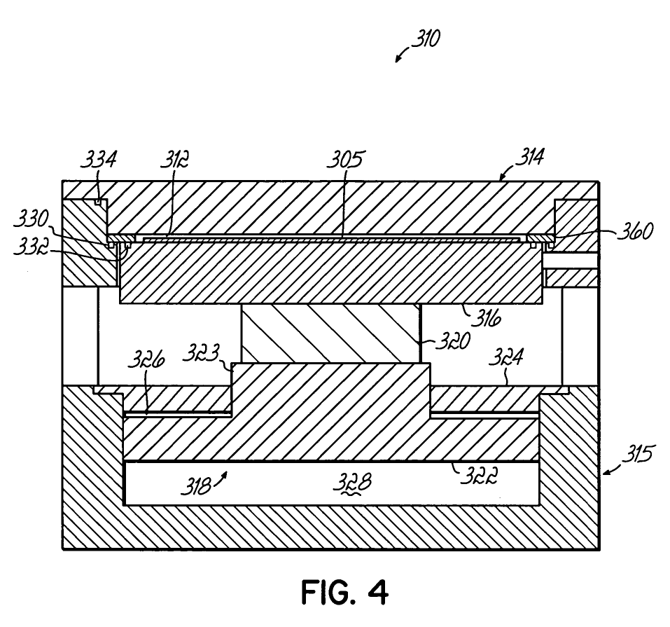

Alternatively, the processing chamber 210 can be configured as described in pending U.S. patent application Ser. No. 09/912,844 (U.S. Patent Application Publication No. 2002/0046707 A1), entitled “High pressure processing chamber for semiconductor substrates”, filed on Jul. 24, 2001, which is incorporated herein by reference in its entirety. For example, FIG. 4 depicts a cross-sectional view of a supercritical processing chamber 310 comprising upper chamber assembly 314, lower chamber assembly 315, platen 316 configured to support substrate 305, and drive mechanism 318 configured to raise and lower platen 316 between a substrate loading/unloading condition and a substrate processing condition. Drive mechanism 318 can further include a drive cylinder 320, drive piston 322 having piston neck 323, sealing plate 324, pneumatic cavity 326, and hydraulic cavity 328. Additionally, supercritical processing chamber 310 further includes a plurality of sealing devices 330, 332, and 334 for providing a sealed, high pressure process space 312 in the processing chamber 310.

As described above with reference to FIGS. 1, and 3, the fluid flow or recirculation system coupled to the processing chamber is configured to circulate the fluid through the processing chamber, and thereby permit the exposure of the substrate in the processing chamber to a flow of fluid.

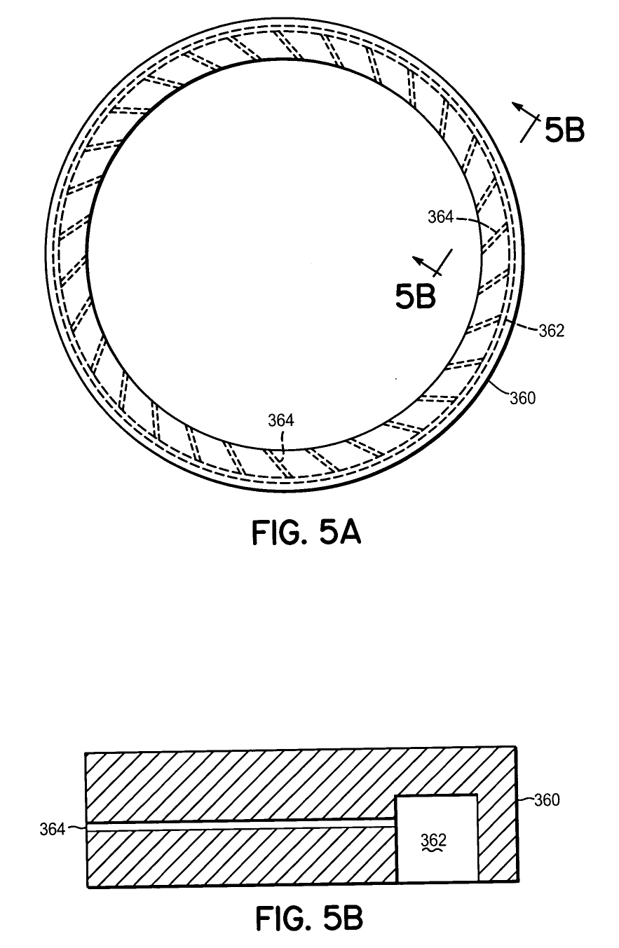

However, as shown in FIG. 4, the fluid, such as supercritical carbon dioxide with or without process chemistry, enters the processing chamber at a peripheral edge of the substrate through one or more inlets coupled to the recirculation system. For example, referring now to FIG. 4 and FIGS. 5A and 5B, an injection manifold 360 is shown as a ring having an annular fluid supply channel 362 coupled to one or more inlets 364. The one or more inlets 364, as illustrated, include forty five (45) injection orifices canted at 45 degrees, thereby imparting azimuthal momentum, or axial momentum, or both, as well as radial momentum to the flow of high pressure fluid through process space 312 above substrate 305. Although shown to be canted at an angle of 45 degrees, the angle may be varied, including direct radial inward injection.

Additionally, the fluid, such as supercritical carbon dioxide, exits the processing chamber adjacent a surface of the substrate through one or more outlets. In doing so, a fluid vortex is formed in the process space 312, creating weak velocities at the peripheral edge of substrate 305, and intense velocities at the center of substrate 305. Additionally, as described in U.S. patent application Ser. No. 09/912,844, the one or more (not shown) outlets can include two outlet holes positioned proximate to and above the center of substrate 305. The flow through the two outlets can be alternated from one outlet to the next outlet using a shutter valve and, therefore, the center of the fluid vortex can be shifted in space between the locations of the two outlets. Although the center of the fluid vortex moves in time and is no longer stationary at the center of substrate 305, the inventors have observed the velocity field to be non-uniform and, consequently, a non-uniform treating rate is observed on substrate 305. For instance, when the flow rate is approximately 30 liters per minute, the magnitude of the velocity at the peripheral edge of the substrate can be approximately 1 meter per second (m/sec), and the magnitude of the velocity substantially near the center of the substrate can be approximately 15 m/sec.

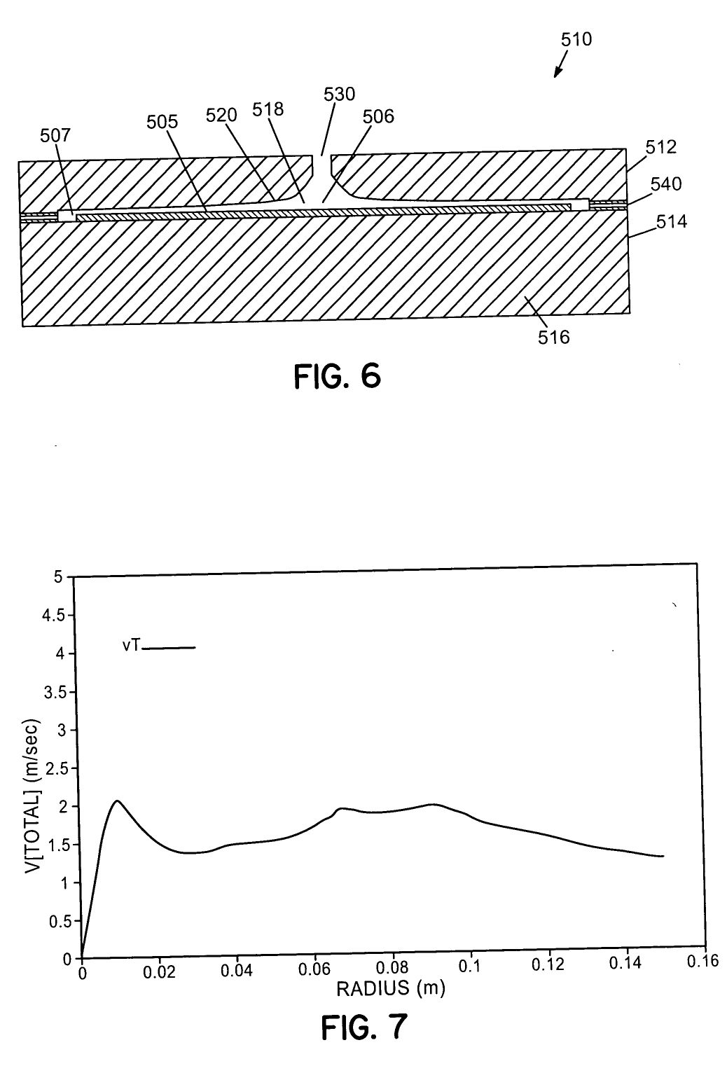

According to one embodiment, a high pressure fluid is introduced to the processing chamber, and discharged from the processing chamber as illustrated in FIG. 6. As shown in FIG. 6, a processing chamber 510 comprises an upper chamber assembly 512 having a ceiling 520 that faces process space 518 and is located above substrate 505, and having a lower chamber assembly 514 with platen 516. Additionally, processing chamber 510 comprises one or more inlets 530 coupled to ceiling 520 above a substantially center portion 506 of substrate 505 and configured to introduce high pressure fluid to processing chamber 510, and one or more outlets 540 located beyond a peripheral edge 507 of substrate 505 and configured to discharge the high pressure fluid from the processing chamber 510.

As illustrated in FIG. 6, a spacing between the upper surface of substrate 505 and ceiling 520 decreases with radial position from proximate the substantially center portion 506 of substrate 505 to the peripheral edge 507 of substrate 505. The rate at which the spacing decreases can decrease with radial position (i.e., the ceiling 520 protrudes as a convex surface towards substrate 505). Alternatively, the spacing varies with radial position according to the relation h(r)=A/r, wherein h(r) represents the spacing, A represents a constant, and r represents the radial position. Alternatively, the spacing varies with radial position such that the radial velocity component of the high pressure fluid flowing radially outward across the upper surface of substrate 505 is substantially uniform. For instance, this condition can be determined for a given flow rate and geometry using a continuum fluid solver, such as CFDRC-ACE, commercially available from CFD Research Corporation (Huntsville, Ala.). In one embodiment, a radial profile of the ceiling comprises a smooth surface, i.e., a continuous slope. In another embodiment, a radial profile of the ceiling comprises one or more linear segments, wherein the slope of the surface is discontinuous at the interconnection between linear segments.

In one embodiment, the one or more inlets provide a flow of high pressure fluid that is moving in a direction initially perpendicular to the substrate surface. In another embodiment, the one or more inlets provide a flow of high pressure fluid that is moving partly in a direction perpendicular to the substrate surface and partly in an azimuthal direction (i.e., a swirl velocity component). In yet another embodiment, the one or more inlets provide a flow of high pressure fluid that is moving partly in a direction perpendicular to the substrate surface and partly in a radial direction. In yet another embodiment, the one or more inlets provide a flow of high pressure fluid that is moving partly in a direction perpendicular to the substrate surface, partly in a radial direction, and partly in an azimuthal direction (i.e., a swirl velocity component).

For example, Table 1 presents one variation of the spacing as a function of radial position. Additionally, FIG. 7 presents the radial variation of the velocity magnitude (i.e., V [TOTAL]=SQRT(u*u+v*v+w*w), where u represents the axial velocity (normal to substrate), v represents the radial velocity (parallel with substrate), and w represents the azimuthal velocity (parallel to substrate)) across the substrate surface according to the solution provided using a continuum fluid solver, such as CFDRC-ACE.

As shown in FIG. 7, the total velocity magnitude is substantially uniform, i.e., V [TOTAL] ˜1.6 m/sec +/−25% (min/max).

TABLE 1

| Radius, r [mm] | Height, h(r) [mm] |
|---|---|
| 5.08 | 10.64 |
| 6.39 | 8.09 |
| 8.09 | 5.65 |
| 9.33 | 5.04 |
| 10.61 | 4.61 |
| 16.05 | 3.94 |
| 41.45 | 2.88 |
| 66.85 | 2.33 |
| 92.25 | 2.04 |
| 150 | 2.04 |

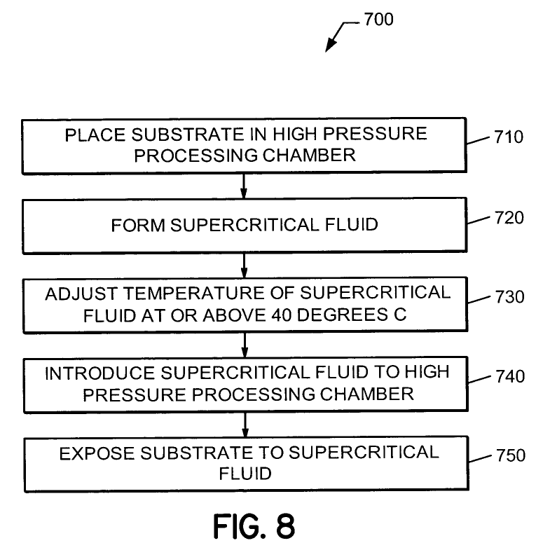

Referring now to FIG. 8, a method of treating a substrate with a fluid in a supercritical state is provided. As depicted in flow chart 700, the method begins in 710 with placing a substrate onto a platen within a high pressure processing chamber configured to expose the substrate to a supercritical fluid processing solution.

In 720, a supercritical fluid is formed by bringing a fluid in a subcritical state to a supercritical state by adjusting the pressure of the fluid to at or above the critical pressure of the fluid, and adjusting the temperature of the fluid to at or above the critical temperature of the fluid. In 730, the temperature of the supercritical fluid is further optionally elevated to a value equal to or greater than 40 degrees C. For example, the temperature of the supercritical fluid is set to equal or greater than 80 degrees C. By way of further example, the temperature of the supercritical fluid is set to equal or greater than 120 degrees C.

In 740, the supercritical fluid is introduced to the high pressure processing chamber through one or more inlets and discharged through one or more outlets. In 750, the substrate is exposed to the supercritical fluid.

Additionally, as described above, a process chemistry can be added to the supercritical fluid during processing. The process chemistry can comprise a cleaning composition, a film forming composition, a healing composition, or a sealing composition, or any combination thereof. For example, the process chemistry can comprise a cleaning composition having a peroxide. In each of the following examples, the temperature of the supercritical fluid is elevated above approximately 40 degrees C. and is, for example, 135 degrees C. Furthermore, in each of the following examples, the pressure of the supercritical fluid is above the critical pressure and is, for instance, 2,900 psi. In one example, the cleaning composition can comprise hydrogen peroxide combined with, for instance, a mixture of methanol (MeOH) and acetic acid (AcOH). By way of further example, a process recipe for removing post-etch residue(s) can comprise three steps including: (1) exposure of the substrate to supercritical carbon dioxide for approximately two minutes; (2) exposure of the substrate to 1 milliliter (ml) of 50% hydrogen peroxide (by volume) in water and 20 ml of 1:1 ratio MeOH:AcOH in supercritical carbon dioxide for approximately three minutes; and (3) exposure of the substrate to 13 ml of 12:1 ratio MeOH:H₂O in supercritical carbon dioxide for approximately three minutes. The second step can be repeated any number of times, for instance, it may be repeated twice. Moreover, any step may be repeated. Additionally, the time duration for each step, or sub-step, may be varied greater than or less than those specified. Further yet, the amount of any additive may be varied greater than or less than those specified, and the ratios may be varied.

In another example, the cleaning composition can comprise a mixture of hydrogen peroxide and pyridine combined with, for instance, methanol (MeOH). By way of further example, a process recipe for removing post-etch residue(s) can comprise two steps including: (1) exposure of the substrate to 20 milliliter (ml) of MeOH and 13 ml of 10:3 ratio (by volume) of 50% hydrogen peroxide (by volume) in water in supercritical carbon dioxide and pyridine for approximately five minutes; and (2) exposure of the substrate to 10 ml of N-methylpyrrolidone (NMP) in supercritical carbon dioxide for approximately two minutes. The first step can be repeated any number of times, for instance, it may be repeated once. Moreover, any step may be repeated. Additionally, the time duration for each step, or sub-step, may be varied greater than or less than those specified. Further yet, the amount of any additive may be varied greater than or less than those specified, and the ratios may be varied.

In another example, the cleaning composition can comprise butanone peroxide combined with, for instance, a mixture of methanol (MeOH) and acetic acid. By way of further example, a process recipe for removing post-etch residue(s) can comprise three steps including: (1) exposure of the substrate to supercritical carbon dioxide for approximately two minutes; (2) exposure of the substrate to 4 milliliter (ml) of butanone peroxide (such as Luperox DHD-9, which is 32% by volume of butanone peroxide in 2,2,4-trimethyl-1,3-pentanediol diisobutyrate) and 12.5 ml of 1:1 ratio MeOH:AcOH in supercritical carbon dioxide for approximately three minutes; and (3) exposure of the substrate to 13 ml of 12:1 ratio MeOH:H₂O in supercritical carbon dioxide for approximately three minutes. The second step can be repeated any number of times, for instance, it may be repeated twice. Moreover, any step may be repeated. Additionally, the time duration for each step, or sub-step, may be varied greater than or less than those specified. Further yet, the amount of any additive may be varied greater than or less than those specified, and the ratios may be varied.

In another example, the cleaning composition can comprise butanone peroxide combined with, for instance, a mixture of methanol (MeOH) and acetic acid. By way of further example, a process recipe for removing post-etch residue(s) can comprise three steps including: (1) exposure of the substrate to supercritical carbon dioxide for approximately two minutes; (2) exposure of the substrate to 8 milliliter (ml) of butanone peroxide (such as Luperox DHD-9, which is 32% by volume of butanone peroxide in 2,2,4-trimethyl-1,3-pentanediol diisobutyrate) and 16 ml of 1:1 ratio MeOH:AcOH in supercritical carbon dioxide for approximately three minutes; and (3) exposure of the substrate to 13 ml of 12:1 ratio MeOH:H₂O in supercritical carbon dioxide for approximately three minutes. The second step can be repeated any number of times, for instance, it may be repeated twice. Moreover, any step may be repeated. Additionally, the time duration for each step, or sub-step, may be varied greater than or less than those specified. Further yet, the amount of any additive may be varied greater than or less than those specified, and the ratios may be varied.

In another example, the cleaning composition can comprise peracetic acid combined with, for instance, a mixture of methanol (MeOH) and acetic acid. By way of further example, a process recipe for removing post-etch residue(s) can comprise three steps including: (1) exposure of the substrate to supercritical carbon dioxide for approximately two minutes; (2) exposure of the substrate to 4.5 milliliter (ml) of peracetic acid (32% by volume of peracetic acid in dilute acetic acid) and 16.5 ml of 1:1 ratio MeOH:AcOH in supercritical carbon dioxide for approximately three minutes; and (3) exposure of the substrate to 13 ml of 12:1 ratio MeOH:H₂O in supercritical carbon dioxide for approximately three minutes. The second step can be repeated any number of times, for instance, it may be repeated twice. Moreover, any step may be repeated. Additionally, the time duration for each step, or sub-step, may be varied greater than or less than those specified. Further yet, the amount of any additive may be varied greater than or less than those specified, and the ratios may be varied.

In another example, the cleaning composition can comprise 2,4-pentanedione peroxide combined with, for instance, N-methylpyrrolidone (NMP). By way of further example, a process recipe for removing post-etch residue(s) can comprise two steps including: (1) exposure of the substrate to supercritical carbon dioxide for approximately two minutes; and (2) exposure of the substrate to 3 milliliter (ml) of 2,4-pentanedione peroxide (for instance, 34% by volume in 4-hydroxy-4-methyl-2-pentanone and N-methylpyrrolidone, or dimethyl phthalate and proprietary alcohols) and 20 ml of N-methylpyrrolidone (NMP) in supercritical carbon dioxide for approximately three minutes. The second step can be repeated any number of times, for instance, it may be repeated twice. Moreover, any step may be repeated. Additionally, the time duration for each step, or sub-step, may be varied greater than or less than those specified. Further yet, the amount of any additive may be varied greater than or less than those specified, and the ratios may be varied.

Additional details regarding high temperature processing are provided in co-pending U.S. patent application Ser. No. 10/987,067, entitled “Method and System for Treating a Substrate Using a Supercritical Fluid”, filed on Nov. 12, 2004; the entire content of which is herein incorporated by reference in its entirety.

In yet another embodiment, the processes described herein can be further supplemented by ozone processing. For example, when performing a cleaning process, the substrate can be subjected to ozone treatment prior to treating with a supercritical processing solution. During ozone treatment, the substrate enters an ozone module, and the surface residues to be removed are exposed to an ozone atmosphere. For instance, a partial pressure of ozone formed in oxygen can be flowed over the surface of the substrate for a period of time sufficient to oxidize residues either partly or wholly. The ozone process gas flow rate can, for example, range from 1 to 50 slm (standard liters per minute) and, by way of further example, the flow rate can range from 5 to 15 slm. Additionally, the pressure can, for example, range from 1 to 5 atmospheres (atm) and, by way of further example, range from 1 to 3 atm. Further details are provided in co-pending U.S. patent application Ser. No. 10/987,594, entitled “A Method for Removing a Residue from a Substrate Using Supercritical Carbon Dioxide Processing”, filed on Nov. 12, 2004, and co-pending U.S. patent application Ser. No. 10/987,676, entitled “A System for Removing a Residue from a Substrate Using Supercritical Carbon Dioxide Processing”, filed on Nov. 12, 2004; the entire contents of which are incorporated herein by reference in their entirety.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A processing system for treating a substrate comprising:
a processing chamber configured to treat said substrate;
a platen coupled to said processing chamber, and configured to support said substrate beneath a ceiling of said processing chamber;
a fluid supply system coupled to said processing chamber, and configured to introduce a high pressure fluid to said processing chamber;
a fluid flow system coupled to said fluid supply system, and configured to flow said high pressure fluid through said processing chamber over said substrate;
one or more inlets coupled to said fluid flow system, and configured to introduce said high pressure fluid to said processing chamber through said ceiling and into a space between said ceiling and said substrate at a substantially center portion of said substrate; and
one or more outlets positioned beyond a peripheral edge of said substrate, and configured to discharge said high pressure fluid from said space,
wherein a height between said ceiling and an upper surface of said substrate monotonically decreases with radial position across said substrate from said substantially center portion of said substrate to said peripheral edge of said substrate.

2. The processing system of claim 1, wherein said fluid includes a supercritical fluid.

3. The processing system of claim 2, wherein said supercritical fluid includes supercritical carbon dioxide (CO₂).

4. The processing system of claim 1, wherein said supercritical fluid is introduced to said processing chamber through said one or more inlets flowing in a direction that is substantially perpendicular to said upper surface of said substrate.

5. The processing system of claim 1, wherein said supercritical fluid is introduced to said processing chamber through said one or more inlets flowing in a direction that is substantially non-perpendicular to said upper surface of said substrate.

6. The processing system of claim 1, wherein said supercritical fluid is introduced to said processing chamber through said one or more inlets so as to generate a swirl velocity component at said substantially center portion of said substrate.

7. The processing system of claim 1, wherein said height decreases with said radial position at a rate that also decreases with said radial position.

8. The processing system of claim 1, wherein said height varies with said radial position according to a relationship substantially of the form A/r, where A represents a constant and r represents said radial position.

9. The processing system of claim 1, wherein said height varies with said radial position such that a radial velocity of said high pressure fluid above said upper surface of said substrate is substantially constant.

10. The processing system of claim 1, wherein said fluid flow system comprises a recirculation system coupled to said one or more inlets and coupled to said one or more outlets, and configured to circulate said high pressure fluid through said processing chamber from said one or more outlets to said one or more inlets.

11. The processing system of claim 1, further comprising:
a process chemistry supply system coupled to said fluid flow system, and configured to introduce a process chemistry to said high pressure fluid.

12. The processing system of claim 11, wherein said process chemistry supply system is configured to introduce a solvent, a co-solvent, a surfactant, a film-forming precursor, or a reducing agent, or any combination thereof.

13. The processing system of claim 11, wherein said process chemistry supply system is configured to introduce: cleaning compositions for removing contaminants, residues, hardened residues, photoresist, hardened photoresist, post-etch residue, post-ash residue, post chemical-mechanical polishing (CMP) residue, post-polishing residue, or post-implant residue, or any combination thereof; cleaning compositions for removing particulate; drying compositions for drying thin films, porous thin films, porous low dielectric constant materials, or air-gap dielectrics, or any combination thereof; film-forming compositions for preparing dielectric thin films, metal thin films, or any combination thereof; healing compositions for restoring the dielectric constant of low dielectric constant (low-k) films; sealing compositions for sealing porous films or any combination thereof.

14. The processing system of claim 11, wherein said process chemistry supply system is configured to introduce a peroxide.

15. The processing system of claim 11, wherein said process chemistry supply system is configured to introduce an organic peroxide, or an inorganic peroxide.

16. The processing system of claim 11, wherein said process chemistry supply system is configured to introduce hydrogen peroxide, butanone peroxide, 2,4-pentanedione peroxide, peracetic acid, t-butyl hydroperoxide, benzoyl peroxide, or m-chloroperbenzoic acid (mCPBA), or any combination thereof.

17. The processing system of claim 11, wherein said process chemistry supply system is configured to introduce said peroxide with one or more of a solvent, a co-solvent, a surfactant, or an etchant.

18. The processing system of claim 1, wherein said processing chamber is further coupled to an ozone processing chamber configured to expose said substrate to ozone.

19. The processing system of claim 1, wherein a temperature of said high pressure fluid ranges from approximately 31 degrees C. to 350 degrees C.

20. The processing system of claim 1, wherein a pressure of said high pressure fluid ranges from approximately 1,070 psi to approximately 10,000 psi.
